(19) United States
(12) Patent Application Publication
(10) Pub. No.: US 2023/0060795 A1
(43) Pub. Date: Mar. 2, 2023

(54) CELL-CONTACTING SYSTEM FOR A BATTERY MODULE AND BATTERY MODULE COMPRISING SUCH A CELL-CONTACTING SYSTEM

(71) Applicant: Diehl AKO Stiftung & Co. KG, Wangen (DE)

(72) Inventor: Mateusz Kurpiel, Wangen (DE)

(21) Appl. No.: 17/861,858

(22) Filed: Jul. 11, 2022

(30) Foreign Application Priority Data
Aug. 31, 2021 (DE) 10 2021 122 422.5

(51) Int. Cl. H01M 50/569; H05K 1/02; H05K 1/11; H01M 50/209; H01M 50/507; H01M 50/519; H01M 10/48; H01M 10/613; H01M 10/647; H01M 10/6554

(52) U.S. Cl. CPC H01M 50/569; H05K 1/0296; H05K 1/115; H01M 50/209; H01M 50/507; H01M 50/519; H01M 10/486; H01M 10/482; H01M 10/613; H01M 10/647; H01M 10/6554; H05K 2201/10151

(57) ABSTRACT

A cell-contacting system for a battery module having an array of a plurality of battery cells. Cell connectors connect the cell terminals of the battery cells. The signal lines of a printed circuit board connect a signal source of one of the cell connectors to a signal management circuit or a connection interface. A plastics material carrier plate fits onto the battery cell array and has a first receiving region for the printed circuit board and a plurality of second receiving regions for one each of the plurality of cell connectors. The carrier plate has a base plate and frame elements for receiving the printed circuit board and the cell connectors. Snap-action hooks on the frame elements allow the printed circuit board or the cell connectors to be snap-fit into the corresponding receiving regions.

### CROSS-REFERENCE TO RELATED APPLICATION

This application claims the priority, under 35 U.S.C. § 119, of German Patent Application DE 10 2021 122 422.5, filed Aug. 31, 2021; the prior application is herewith incorporated by reference in its entirety.

### FIELD AND BACKGROUND OF THE INVENTION

The present invention relates to a cell-contacting system for a battery module having an array of a plurality of battery cells. The invention further pertains to a battery module having such a cell-contacting system.

Cell management controllers (CMC), which monitor the individual battery cells of the battery module in order to carry out, for example, charging processes and the balancing of voltages and states of charge, temperature-control processes, etc. for the battery cells, require a cell-contacting system for contacting the battery cells in order to obtain corresponding measurement signals, for example of the potentials and temperatures of the battery cells. Conventional cell-contacting systems usually require a high assembly effort and spatial requirement for the construction of the cell-contacting system.

### SUMMARY OF THE INVENTION

It is accordingly an object of the invention to provide a cell contacting system and a battery module which overcome a variety of disadvantages of the heretofore-known devices and methods of this general type and which provides for an improved cell-contacting system having a simple construction and a space-saving structure.

With the above and other objects in view there is provided, in accordance with the invention, a cell-contacting system for a battery module having a battery cell array of a plurality of battery cells, the cell-contacting system comprising:

a plurality of cell connectors for electrically conductively connecting cell terminals of different battery cells;

a printed circuit board with a plurality of signal lines, each for connecting a signal source of one of said plurality of cell connectors to a signal management circuit or to a connection interface, wherein each of the signal sources of said plurality of cell connectors is electrically conductively connected via at least one connection element to one of said plurality of signal lines of said printed circuit board; and

a carrier plate to be fitted onto the battery cell array, said carrier plate having a first receiving region for said printed circuit board and a plurality of second receiving regions each for one of said plurality of cell connectors;

said carrier plate being a plastics material carrier plate having:
a plate base, which extends over an entirety of the battery cell array, said plate base being formed, in each of said plurality of second receiving regions, with at least one through-opening for contacting the cell terminals of the corresponding battery cells;
on a side of said plate base facing away from the battery cell array, a first frame element, which at least partially surrounds said first receiving region for said printed circuit board;
on the side of said plate base facing away from the battery cell array, a plurality of second frame elements, which at least partially surround one each of said plurality of second receiving regions for said cell connector;
on said first frame element, at least one first snap-action hook for snap-fitting said printed circuit board in said first receiving region of said carrier plate; and
on each of said plurality of second frame elements, at least one second snap-action hook for snap-fitting a cell connector in the corresponding second receiving region of said carrier plate.

In other words, the cell-contacting system according to the invention for a battery module with an array of a plurality of battery cells has a plurality of cell connectors for electrically conductively connecting the cell terminals of different battery cells; a printed circuit board with a plurality of signal lines, each for connecting a signal source of one of the plurality of cell connectors to a signal management circuit or a connection interface, wherein the signal sources of the plurality of cell connectors are each electrically conductively connected via at least one connection element to one of the plurality of signal lines of the printed circuit board; and a plastics material carrier plate, which can be fitted onto the battery cell array and has a first receiving region for the printed circuit board as well as a plurality of second receiving regions for one each of the plurality of cell connectors. In accordance with the invention, a special carrier plate is proposed, which (i) has a plate base, which extends over the entire battery cell array, wherein the plate base has, in each of the plurality of second receiving regions, at least one through-opening for contacting the cell terminals of the corresponding battery cells; (ii) has, on the side of the plate base facing away from the battery cell array, a first frame element, which at least partially surrounds the first receiving region for the printed circuit board; (iii) also has, on the side of the plate base facing away from the battery cell array, a plurality of second frame elements, which each at least partially surround one of the plurality of second receiving regions for the cell connectors; (iv) has, on the first frame element, at least one first snap-action hook for snap-fitting the printed circuit board in the first receiving region of the carrier plate; and (v) has, on each of the plurality of second frame elements, at least one second snap-action hook for snap-fitting a cell connector in the corresponding second receiving region of the carrier plate.

The use of such a carrier plate having frame elements around the receiving regions of the printed circuit board and the cell connectors as well as snap-action hooks provided on the frame elements for snap-fitting (i.e., inserting in a substantially form-fitting manner) the printed circuit board or the plurality of cell connectors into the corresponding receiving regions allows a simple (possibly even automated) and rapid mounting of the printed circuit board and of the cell connectors on the carrier plate without additional fastening elements (for example screws) and without additional fastening processes. In addition, the carrier plate with the plate base and the frame elements can have a relatively low height on the whole by the use of such snap-action hooks, wherein the height of the cell-contacting system and thus of the entire battery module in comparison to the conventional cell-contacting systems that use other mounting systems can also be reduced. In addition, a mounting by means of snap-action hooks is somewhat flexible in principle, so that, in contrast to rigid mounting systems (for example with screws), it is also possible to compensate for deformations (for example temperature-induced expansions) and movements of the battery cells.

The first frame element, which at least partially surrounds the first receiving region for the printed circuit board, can be designed within the scope of the invention in the form of an individual frame element with or without gaps therein or in the form of a plurality of frame sub-elements with or without distances therebetween. The plurality of second frame element, which each at least partially surround a second receiving region for a cell connector, can be designed within the scope of the invention in each case in the form of an individual frame element with or without gaps therein or in the form of a plurality of frame sub-elements with or without distances therebetween. In addition, within the scope of the invention, all or some of the plurality of second frame elements, which each at least partially surround a second receiving region for a cell connector, can be combined with one another to form a component. The first and second frame elements can be fastened as separate component parts to the plate base or can preferably be formed in one piece with the plate base. The first and second snap-action hooks are preferably each formed integrally with the corresponding frame elements. The snap-action hooks can also be referred to as snap-fit elements.

The cell-contacting system of the invention can be realized in principle with any types/constructions of cell connectors and printed circuit boards. The cell-contacting system of the invention can also be realized in principle with any types/constructions of electrical connection elements between printed circuit board and cell connectors, wherein the connection elements can preferably be designed as press-fit connection elements, as are described in detail in our copending German patent application DE 10 2021 116 447.8 and its U.S. counterpart (Atty. Docket DSC-AP-0657), which is herewith incorporated by reference.

The cell-contacting system preferably has at least one signal management circuit connected to the signal lines of the printed circuit board. The at least one signal management circuit can, for example, be integrated into the printed circuit board or connected to the printed circuit board as an external circuit via a corresponding connection interface. The integrated or external signal management circuit is additionally preferably connected to a battery module controller via a connection interface. The cell-contacting system, the signal management circuit and the battery module controller can also be referred to together as a cell management controller (CMC).

In accordance with an added feature of the invention, the at least one first snap-action hook, on its underside facing the plate base, is substantially parallel to the plate base. Alternatively or additionally, the plurality of second snap-action hooks, on their underside facing the plate base, are each also substantially parallel to the plate base. The undersides of the snap-action hooks are thus also substantially parallel to the printed circuit board or the cell connectors. This embodiment of the snap-action hooks achieves a particularly small efficient design of the snap-action hooks, so that the frame elements and thus the entire carrier plate can also have a particularly low height.

In accordance with an additional feature of the invention, the at least one first snap-action hook is designed such that it is prestressed in the direction of the plate base. Alternatively or additionally, the plurality of second snap-action hooks are also each designed such that they are prestressed in the direction of the plate base. As a result of this measure, with manufacturing tolerances of the printed circuit board and/or the cell connectors and in the event of movements of the printed circuit board and/or the cell connectors (for example caused by expansions and/or movements of the battery cells 12), the snap-action hooks remain in contact with the printed circuit board or the cell connectors, so that these are fixed securely to the carrier plate.

In accordance with another feature of the invention, the at least one first snap-action hook and/or the plurality of second snap-action hooks are each elastic. The elastic design of the snap-action hooks can be achieved, for example, by their material selection, their structure and/or their coupling to the corresponding frame elements. As a result of this measure, the placement of the printed circuit board or of the cell connectors into the corresponding receiving regions of the carrier plate is simplified. In addition, this measure likewise supports the advantages that the snap-action hooks remain in contact with the printed circuit board or the cell connectors, even with manufacturing tolerances and movements of the printed circuit board or the cell connectors (in horizontal directions), so that these are fixed securely to the carrier plate, and that deformations and movements of the battery cells can be better compensated during operation of the battery module.

In accordance with a further feature of the invention, the plate base of the carrier plate, in the first receiving region for the printed circuit board, has at least one elastic portion, which is elastic in relation to the thickness direction of the plate base. As a result of this measure, deformations and movements of the battery cells can be even better compensated in the vertical direction during operation of the battery module.

Preferably, the signal sources of the cell connectors have at least one voltage tap point provided on one of the plurality of cell connectors and/or at least one temperature-measuring device mounted on one of the plurality of cell connectors. Preferably, all cell connectors are each provided with a voltage tap point connected to a signal line of the printed circuit board. Preferably, some or even all of the cell connectors each have a temperature-measuring device attached thereto that is connected to a signal line of the printed circuit board. The at least one temperature-measuring device preferably has a sensor printed circuit board with a temperature-sensing element, the sensor printed circuit board being connected to the corresponding cell connector via a contact element and being connected to a signal line of the printed circuit board via a connection element.

In accordance with again an added feature of the invention, the plate base of the carrier plate, within the first receiving region or outside the first receiving region and the second receiving regions, has at least one ventilation opening, for example in the form of a plurality of holes or a gap. In the first-mentioned variant, the printed circuit board likewise has at least one ventilation opening, which cooperates with the at least one ventilation opening of the plate base. The ventilation openings can support a cooling process of the battery cells under the cell-contacting system.

With the above and other objects in view there is also provided, in accordance with the invention, a battery module that has an array of a plurality of battery cells and an above-described cell-contacting system of the invention on the battery cell array. With this battery module, the same advantages can be achieved as explained above in conjunction with the cell-contacting system according to the invention.

The battery cells are connected to each other via the cell connectors of the cell-contacting system and can be connected to a consumer or a charging system via an electrical connection of the battery module. The invention is not limited to any particular type, number, size or arrangement of the plurality of battery cells. In particular, the invention is also usable for Li-ion battery modules.

The battery module generally further has at least one battery module controller for operating the battery module, said battery module controller being connected to the at least one signal management circuit (integrated in the printed circuit board or connected to the printed circuit board as an external circuit via a connection interface). The module controller performs, for example, charging processes, balancing of the voltages and the states of charge, temperature-control processes such as, in particular, cooling processes, and the like, at least partially depending on the measurement signals obtained by the cell-contacting system.

The battery module preferably has a module housing for receiving the battery cell array. The module housing preferably has a housing opening, through which the cell terminals of the battery cells are accessible, wherein the carrier plate of the cell-contacting system is mounted in or on this housing opening of the module housing.

The invention is advantageously applicable to battery modules for vehicles, in particular electric vehicles and hybrid vehicles and in particular motor vehicles and motorcycles, and also to energy storage systems and other electrical appliances (for example, electronic household appliances).

Other features which are considered as characteristic for the invention are set forth in the appended claims.

Although the invention is illustrated and described herein as embodied in a cell-contacting system for a battery module and a battery module comprising such a cell-contacting system, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 shows a perspective view of a battery module according to an exemplary embodiment of the invention;

FIG. 2 shows a plan view of a carrier plate of the cell-contacting system according to an exemplary embodiment of the invention for the battery module of FIG. 1;

FIG. 3A shows an enlarged perspective partial plan view of the carrier plate from FIG. 2 without mounted printed circuit board;

FIG. 3B shows an enlarged perspective partial plan view of the carrier plate from FIG. 2 with mounted printed circuit board;

FIG. 4A shows an enlarged, partial perspective view from above of the carrier plate from FIG. 2 without mounted cell connectors; and

FIG. 4B shows an enlarged, partial perspective view of the carrier plate from FIG. 2 with mounted cell connector.

### DETAILED DESCRIPTION OF THE INVENTION

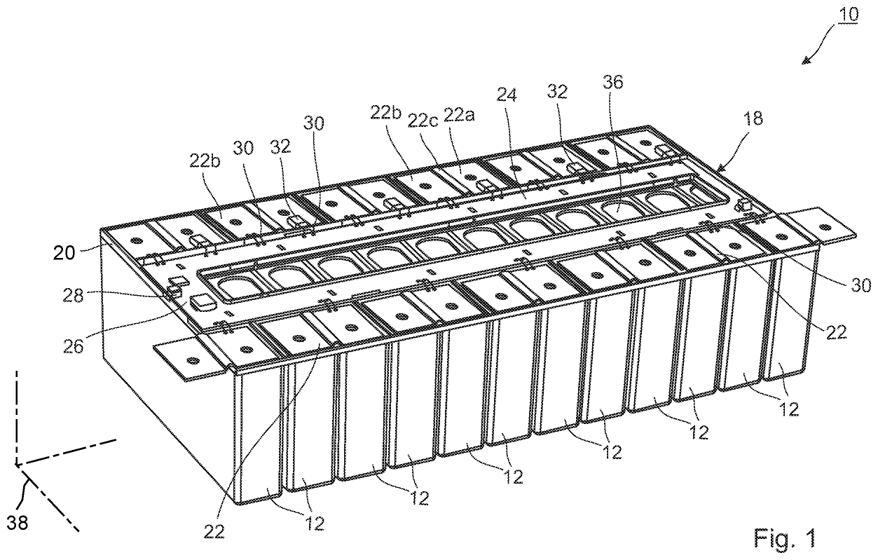

With reference to FIGS. 1 to 4, an exemplary embodiment of a battery module will be explained in an exemplary manner with an exemplary embodiment of a cell-contacting system according to the invention defined in the claims.

The battery module 10 has an array of a plurality of battery cells (for example Li-ion battery cells) 12. In the exemplary embodiment, the battery cells 12 are arranged side by side and each have a negative terminal in the upper or lower end region and a positive terminal in the lower or upper end region, wherein the negative and positive terminals (cell terminals) of the battery cells 12 are arranged alternately so that a negative terminal of one battery cell is next to a positive terminal of an adjacent battery cell. The battery cell array is generally arranged in a module housing 38, wherein the module housing has a housing opening through which the upper end region with the cell terminals of the battery cell array is accessible.

The battery module 10 further has a cell-contacting system 18 arranged above the battery cell array 12. The cell-contacting system 18 is in this case mounted in or on the housing opening of the schematically indicated module housing 38.

The cell-contacting system 18 has a plurality of cell connectors 22 forming a power supply line system. In this exemplary embodiment, the cell connectors 22 each have two contact regions 22a, 22b and a (preferably elastic) compensation region 22c between the two contact regions 22a, 22b and are mounted on the battery cells 12 such that they each couple the negative terminal of a battery cell 12 to the positive terminal of an adjacent battery cell 12 via their two contact regions 22a, 22b, resulting in a series connection of the battery cells 12 in the battery module 10. The battery cells 12 are additionally connectable to a consumer or a charging system via an electrical connection of the battery module 10.

The cell-contacting system 18 further has a, for example, rigid printed circuit board 24 forming the signal line system and disposed over the battery cells 12 in the region between the two rows of cell connectors 22 along the entire length of the battery cell array. The shape and size of the printed circuit board 24 can, in principle, be adapted to any constructions of battery module, in particular to any arrangements, sizes or numbers of battery cells.

As shown in FIG. 1, the printed circuit board 24 has a large gap for a plurality of ventilation openings 36 of the cell-contacting system 18 for supporting a cooling process of the battery cells 12 located thereunder.

As indicated in FIG. 1 for the sake of convenience, the printed circuit board 24 has a plurality of signal lines each connecting a signal source of a cell connector 22 to an electronic signal management circuit 26. The signal management circuit 26 is configured, for example, to perform the voltage measurement process and to evaluate the measurement signals obtained from the signal sources of the cell connectors 22. In this exemplary embodiment, the signal management circuit 26 is integrated on the printed circuit board 24 and connected to a connection interface 28, via which the signal management circuit 26 can be connected to a battery module controller. This battery module controller serves, for example, to perform charging processes, balancing of the voltages and the states of charge, temperature-control processes such as, in particular, cooling processes, etc., these processes being performed at least partially depending on the measurement signals obtained by the cell-contacting system 18 or the measurement values obtained by the signal management circuit 26 thereof. In an alternative embodiment of the invention, the signal management circuit 26 can also be designed externally to the printed circuit board 24. In this case, the signal lines of the printed circuit board 24 are directly connected to the connection interface 28 and the external signal management circuit is coupled to the connection interface 28 of the printed circuit board 24 and is additionally coupled to the battery module controller via a further connection interface.

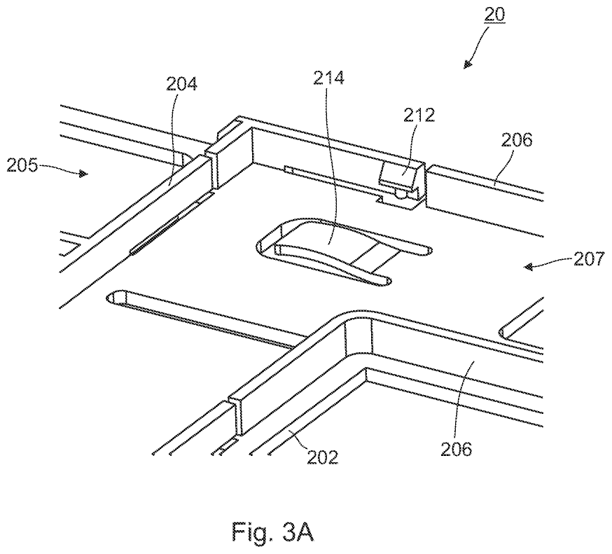

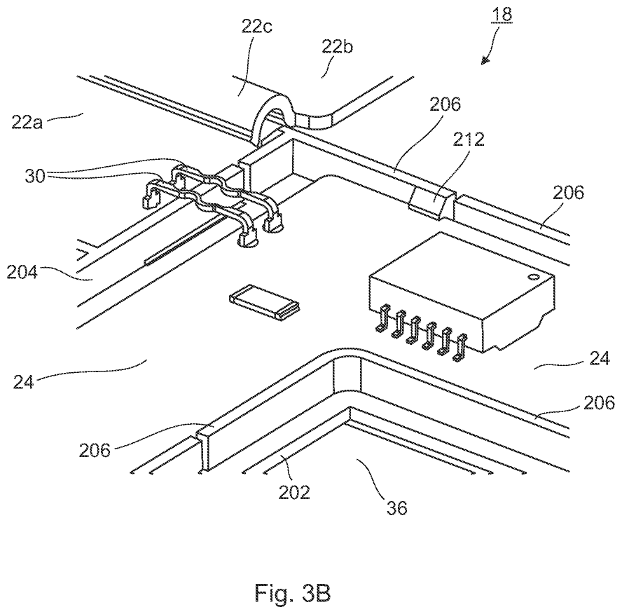

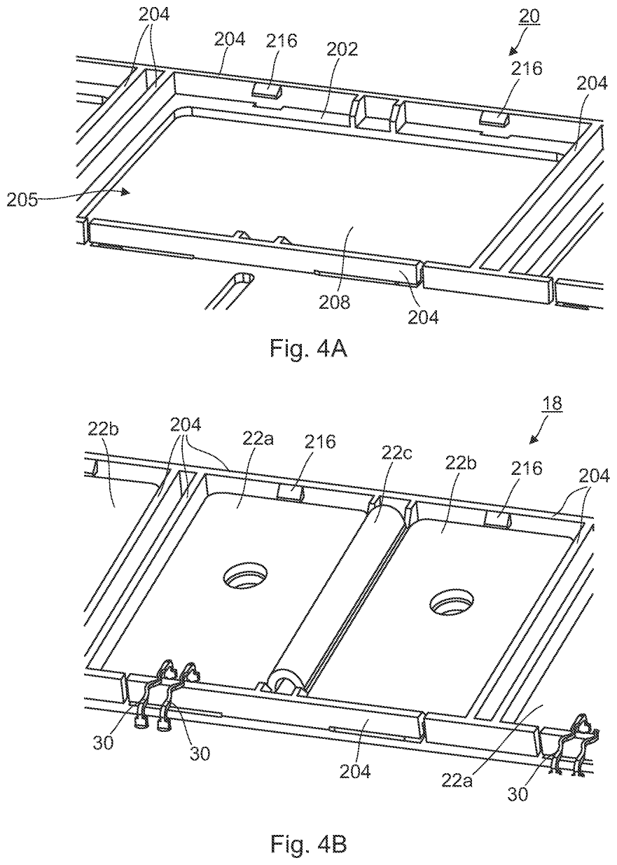

As indicated in FIG. 1, there are two types of signal sources in this cell-contacting system 18. Firstly, all (or, optionally only a majority) of the cell connectors 22 have a voltage tap point as a first signal source type for measuring the voltage of the battery cells 12. The voltage tap points can each be formed directly by a contact region 22a, 22b of a cell connector 22. In addition, a few (optionally also all) of the cell connectors 22 have a temperature-measuring device 32 as a second signal source type for measuring the temperature of the battery cells 12. The temperature-measuring devices 32 for example have a sensor printed circuit board with a temperature-sensing element, wherein the sensor printed circuit board is connected via a contact element to the corresponding cell connector 22. To connect the voltage tap points and the temperature-measuring devices 32 to the signal lines of the printed circuit board 24, at least one (one-part or multi-part) connection element 30 is provided in each case. The structures of these connection elements 30 are, in principle, arbitrary within the scope of the invention. As can be seen in particular in FIGS. 3B and 4B, in this exemplary embodiment the connection elements, however, are preferably designed as press-fit connection elements, which achieve a simple, quick and automated connection of the signal sources to the signal line system formed by the printed circuit board. Such advantageous press-fit connection elements are described in detail in our above-noted patent application DE 10 221 116 447.8 and its US counterpart (Atty. Docket DSC-AP-657), which is incorporated by reference.

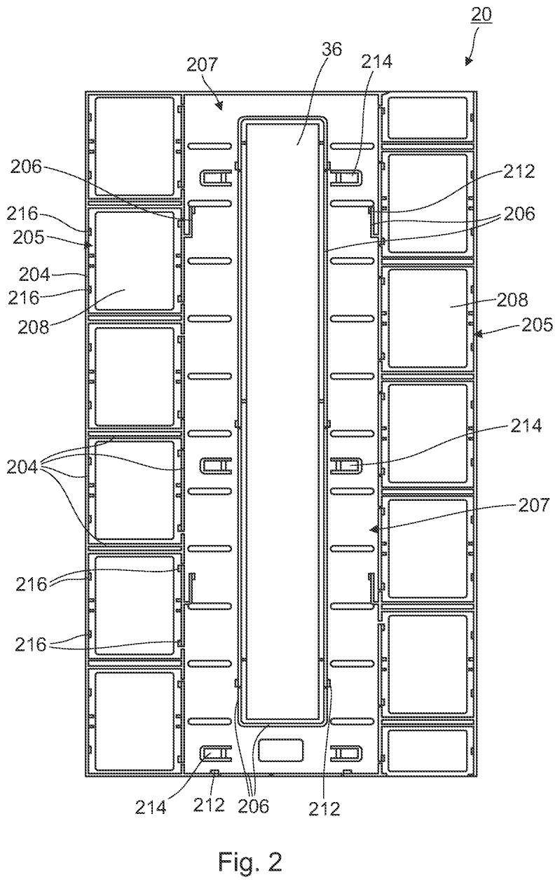

As shown in FIG. 1, the printed circuit board 24 and the cell connectors 22 are in each case mounted on a carrier plate 20, which is likewise part of the cell-contacting system 18. The cell-contacting system 18 is mounted via the carrier plate 20 on the module housing and thus on the battery cell array. The special structure of the carrier plate 20 and the special type of fastening of the printed circuit board 24 and of the cell connectors 22 on the carrier plate 20 will be explained in greater detail with reference to FIGS. 2 to 4.

FIG. 2 shows, by way of example, a carrier plate 20 of the cell-contacting system 18, which is formed as a plastics material carrier plate 20. The carrier plate 20 has a first receiving region 207 for receiving the printed circuit board 24 and a plurality of second receiving regions 205, for receiving one each of the plurality of cell connectors 22.

The carrier plate 20 has a substantially planar plate base 202, which extends over the entire battery cell array. In each of the plurality of second receiving regions 205, the plate base 202 has at least one through-opening 208, through which the cell connectors 22 can then contact the cell terminals of the corresponding battery cells 12.

In this exemplary embodiment, in addition to the first and second receiving regions 207, 205 for the printed circuit board 24 and the cell connectors 22, the plate base 202, in accordance with the structure of the printed circuit board 24, also has a central elongate gap, which serves as a ventilation opening 36. If the printed circuit board 24 is provided with one or more holes as ventilation openings in an alternative embodiment, the plate base 202 is designed accordingly with one or more through-openings within the first receiving region 207 for the printed circuit board 24.

As can be seen in FIG. 2, the carrier plate 20, on its side of the plate base 202 facing away from the battery cell array, has a multi-part first frame element 206, which surrounds the first receiving region 207 for the printed circuit board 24 inwardly and outwardly. In addition, the carrier plate 20, on its side of the plate base 202 facing away from the battery cell array, has a plurality (in this exemplary embodiment, in each case one-part) second frame elements 204, which surround one each of the plurality of second receiving regions 205 for the cell connectors 22. The first and second frame elements 206, 204 are likewise plastics material elements and are preferably formed integrally with the plate base 202.

To insert and fix the printed circuit board 24 in the first receiving region 207 of the carrier plate 20 in a substantially form-fitting manner, a plurality of first snap-action hooks (snap-fit elements) 212 are provided on the multi-part first frame element 206, preferably are formed in one piece with the first frame element 206. As shown more precisely in FIGS. 3A and 3B, the first snap-action hooks 212, on their underside facing the plate base 202, are substantially parallel to the plate base 202 and thus also parallel to the received printed circuit board 24, whereby they can be formed with a relatively low height. In addition, the first snap-action hooks 212 are preferably each prestressed and/or elastic in the direction of the plate base 202. With this construction of the carrier plate 20, the printed circuit board 24 can be easily inserted into the first receiving region 207 and fixed therein, without additional fixing processes with additional fastening elements having to be performed, and the carrier plate can have a relatively low height.

As shown in FIGS. 2 and 3A, the plate base 202 of the carrier plate 20 in the first receiving region 207 for the printed circuit board 24 preferably has one or more elastic portions 214, which are elastic in relation to the thickness direction of the plate base 202.

As a result of this structure of the carrier plate 20 with the first frame element 206 and the special first snap-action hooks 212, even with manufacturing tolerances and movements of the printed circuit board 24 in horizontal and vertical directions, the first snap-action hooks 212 remain in contact with the printed circuit board 24, so that these are fixed securely to the carrier plate 20, and also deformations and movements of the battery cells 12 can be compensated during operation of the battery module 10. Due to the elastic portions 214 of the plate base 202 in the first receiving region 207, deformations and movements of the battery cells 12 in the vertical direction during operation of the battery module 10 can be even better compensated.

To insert and fix the cell connectors 22 in the second receiving regions 205 of the carrier plate 20 in a substantially form-fitting manner, a plurality of second snap-action hooks (snap-fit elements) 216 are provided on the second frame elements 204 and are preferably formed in one piece with the corresponding second frame element 204. As shown more precisely in FIGS. 4A and 4B, the second snap-action hooks 216, on their underside facing the plate base 202, are substantially parallel to the plate base 202 and thus also parallel to the received cell connectors 22, whereby they can be formed with a relatively low height. In addition, the second snap-action hooks 216 are preferably each prestressed and/or elastic in the direction of the plate base 202. With this construction of the carrier plate 20, the cell connectors 22 can be easily inserted into the second receiving regions 205 and fixed therein, without additional fixing processes with additional fastening elements having to be performed, and the carrier plate can have a relatively low height.

As a result of this structure of the carrier plate 20 with the second frame elements 204 and the special second snap-action hooks 216, even with manufacturing tolerances and movements of the cell connectors 22, the second snap-action hooks 216 remain in contact with the corresponding cell connectors 22, so that these are fixed securely to the carrier plate 20, and also deformations and movements of the battery cells 12 can be compensated during operation of the battery module 10.

The above-described battery module 10 with the cell-contacting system 18 according to the invention can be used, for example, for vehicles, in particular electric vehicles and hybrid vehicles and in particular motor vehicles and motorcycles, or for energy storage systems or for other electrical appliances (for example electronic household appliances).

The scope of protection of the invention is defined by the appended set of claims. The exemplary embodiments explained above, inclusive of a few variants, of the battery module and of the cell-contacting system are intended in particular for improved comprehension of the invention and are not intended to limit the scope of protection. A person skilled in the art will be able to identify further variants with the scope of protection of the invention that are based, for example, on further combinations of features from the above exemplary embodiments, on individual omitted features of the above exemplary embodiments and/or on individual modified features of the above exemplary embodiments.

The following is a summary list of reference numerals and the corresponding structure used in the above description of the invention:
10 battery module
12 battery cells
18 cell-contacting system
20 carrier plate
202 plate base
204 second frame elements (for cell connector)
205 second receiving regions (for cell connector)
206 first frame elements (for printed circuit board)
207 first receiving region (for printed circuit board)
208 through-openings in second receiving regions
212 first snap-action hooks on first frame elements (for printed circuit board)
214 elastic portions in plate base
216 second snap-action hooks on second frame elements (for cell connector)
22 cell connectors (power supply line system)
22a contact regions of the cell connectors
22b contact regions of the cell connectors
22c compensation regions of the cell connectors
24 printed circuit board (signal line system)
26 signal management circuit
28 connection interface
30 connection elements
32 temperature-measuring device
36 ventilation openings
38 module housing

1. A cell-contacting system for a battery module having a battery cell array of a plurality of battery cells, the cell-contacting system comprising:
a plurality of cell connectors for electrically conductively connecting cell terminals of different battery cells;
a printed circuit board with a plurality of signal lines, each for connecting a signal source of one of said plurality of cell connectors to a signal management circuit or to a connection interface, wherein each of the signal sources of said plurality of cell connectors is electrically conductively connected via at least one connection element to one of said plurality of signal lines of said printed circuit board; and
a carrier plate to be fitted onto the battery cell array, said carrier plate having a first receiving region for said printed circuit board and a plurality of second receiving regions each for one of said plurality of cell connectors;
said carrier plate:
being a plastics material carrier plate;
having a plate base, which extends over the entire battery cell array, said plate base being formed, in each of said plurality of second receiving regions, with at least one through-opening for contacting the cell terminals of the corresponding battery cells;
having, on a side of said plate base facing away from the battery cell array, a first frame element, which at least partially surrounds said first receiving region for said printed circuit board;
having, on the side of said plate base facing away from the battery cell array, a plurality of second frame elements, which at least partially surround one each of said plurality of second receiving regions for said cell connector;
having, on said first frame element, at least one first snap-action hook for snap-fitting said printed circuit board in said first receiving region of said carrier plate; and
having, on each of said plurality of second frame elements, at least one second snap-action hook for snap-fitting a cell connector in the corresponding second receiving region of said carrier plate.

2. The cell-contacting system according to claim 1, wherein at least one of the following is true:
said at least one first snap-action hook, on an underside thereof facing said plate base, is parallel to said plate base; or
each of said plurality of second snap-action hooks, on an underside thereof facing said plate base, is parallel to said plate base.

3. The cell-contacting system according to claim 1, wherein each of said at least one first snap-action hook and/or said plurality of second snap-action hooks is configured to be prestressed in a direction of said plate base.

4. The cell-contacting system according to claim 1, wherein each of said at least one first snap-action hook and/or said plurality of second snap-action hooks is elastic.

5. The cell-contacting system according to claim 1, wherein said plate base of said carrier plate, in said first receiving region, has at least one elastic portion, which is elastic in a thickness direction of said plate base.

6. The cell-contacting system according to claim 1, wherein said signal sources of said cell connectors have at least one voltage tap point provided on one of said plurality of cell connectors and/or at least one temperature-measuring device mounted on one of said plurality of cell connectors.

7. The cell-contacting system according to claim 6, wherein said temperature-measuring device has a sensor printed circuit board with a temperature-sensing element, said sensor printed circuit board being connected to a cell connector via a contact element and being connected to one of said plurality of signal lines of said printed circuit board via a connection element.

8. The cell-contacting system according to claim 1, wherein said plate base of said carrier plate is formed with at least one ventilation opening.

9. The cell-contacting system according to claim 8, wherein said ventilation opening is formed within said first receiving region or outside said first receiving region and said second receiving regions.

10. A battery module, comprising:
a battery cell array of a plurality of battery cells; and
a cell-contacting system according to claim 1 disposed on said battery cell array.

11. The battery module according to claim 10, further comprising a module housing for receiving said battery cell array, said module housing having a housing opening through which cell terminals of said battery cells are accessible, and wherein the carrier plate of said cell-contacting system is mounted in or on said housing opening of said module housing.
